(19) United States
(12) Patent Application Publication
(10) Pub. No.: US 2013/0321039 A1
(43) Pub. Date: Dec. 5, 2013

(54) DRIVE UNIT FOR MEASURING DEVICE AND DRIVE METHOD THEREFOR

(71) Applicant: CANON KABUSHIKI KAISHA, Tokyo (JP)

(72) Inventor: Yasuhiro Soeda, Yokohama-shi (JP)

(73) Assignee: CANON KABUSHIKI KAISHA, Tokyo (JP)

(21) Appl. No.: 13/897,018

(22) Filed: May 17, 2013

(30) Foreign Application Priority Data
Jun. 1, 2012 (JP) 2012-126095

(51) Int. Cl. H03K 3/01

(52) U.S. Cl. CPC H03K 3/01
USPC 327/111

(57) ABSTRACT

A measuring device comprises a plurality of variable capacitors as sensor elements. The plurality of variable capacitors are provided with a drive circuit for each pair. The first electrodes of the two variable capacitors in each pair are electrically connected to each other. The drive circuit for each pair includes a bias supply for applying two AC bias voltages relatively 90° out of phase to the second electrodes respectively of the two variable capacitors to produce an output signal at the first electrodes connected to each other, a multiplier for multiplying the output signal by two AC signals relatively 90° out of phase to produce two multiplication signals, and an integrator for integrating the two multiplication signals for each cycle of the corresponding AC bias voltages to acquire two integration signals for the two variable capacitors.

### BACKGROUND OF THE INVENTION

1. Field of the Invention

The present invention relates to a drive unit for a measuring device, in particular a drive circuit for a capacitance type transducer used for an ultrasound probe of an ultrasonograph, and a drive method therefor.

2. Description of the Related Art

There is a diagnostic principle using a photoacoustic system as one of diagnostic principles using an ultrasonic wave. The photoacoustic system uses a photoacoustic vibration such as an ultrasonic vibration generated by instantaneous thermal expansion of a tissue which has absorbed a laser beam when the inside of a biological body is irradiated with a pulsed laser beam. The photoacoustic vibration is received on the body surface to acquire information on the inside of the biological body. For the reception of the ultrasonic vibration, an ultrasonic transducer is used. As one type of ultrasonic transducers, there is a capacitance type ultrasonic transducer. The capacitance type ultrasonic transducer is composed of, for example, a space maintained in a substantially vacuum condition, which is called “cavity”, and two electrodes provided with the cavity therebetween. One of the electrodes is provided on a thin film called “membrane” and supported so as to vibrate. The other of the electrodes is fixed onto a substrate of the capacitance type ultrasonic transducer. Hereinafter, the electrode supported so as to vibrate is also referred to as “vibrating electrode” and the electrode fixed onto the substrate is referred to as “fixed electrode”.

When the capacitance type ultrasonic transducer (hereinafter, also referred to simply as “ultrasonic transducer”) receives an ultrasonic wave, the membrane vibrates and a distance between the two electrodes changes. The change in the distance between the electrodes changes a capacitance between the two electrodes. While a voltage is applied between the two electrodes, the change in capacitance is converted into a current signal. In this configuration, a structural unit of the ultrasonic transducer composed of one cavity and two opposed electrodes is referred to as “cell”. In addition, a structural unit composed of a plurality of cells electrically connected to each other is referred to as “element”. In an ultrasonic transducer used for an ultrasonograph, normally a plurality of elements are arranged in a 1D (one-dimensional) or 2D (two-dimensional) array. A drive circuit is provided for each element, and each drive circuit is referred to as “channel”. Since a change in the distance between the electrodes changes the capacitance therebetween, the element is able to be considered to be a variable capacitor in an electric circuit.

Regarding the drive technology of the foregoing ultrasonic transducer, there is a suggestion of decreasing the number of drive circuits of the ultrasonic transducer by connecting electrodes between elements (see Japanese Patent Application Laid-Open No. 2008-022887).

In the technique described in Japanese Patent Application Laid-Open No. 2008-022887, however, a distance between a plurality of elements increases in some cases though the number of channels of the ultrasonic transducer decreases. Therefore, it is an object of the present invention to provide a technique capable of decreasing the number of drive circuits without increasing the distance between variable capacitors such as elements.

### SUMMARY OF THE INVENTION

In view of the above problem, the present invention provides a drive unit for a measuring device comprising a plurality of variable capacitors as sensor elements each having first and second electrodes opposed to each other, the plurality of variable capacitors being provided with a drive circuit for each pair, wherein the first electrodes of the two variable capacitors in each pair are electrically connected to each other, and wherein the drive circuit for each pair includes a bias supply which applies two AC bias voltages to the second electrodes respectively of the two variable capacitors to produce an output signal at the first electrodes connected to each other of the two variable capacitors in each pair, the two AC bias voltages being relatively 90° out of phase with respect to each other, a multiplier which multiplies the output signal by two AC signals to produce two multiplication signals, the two AC signals being relatively 90° out of phase with respect to each other, and an integrator which integrates the two multiplication signals for each cycle of the corresponding AC bias voltages to acquire two integration signals for the two variable capacitors in each pair. The variable capacitors are, for example, elements of a capacitance type ultrasonic transducer.

Moreover, in view of the above problem, the present invention provides a drive method for a measuring device comprising a plurality of variable capacitors as sensor elements each having first and second electrodes opposed to each other, the method including the steps of electrically connecting the first electrodes of the two variable capacitors in each pair of the plurality of variable capacitors, applying two AC bias voltages to the second electrodes respectively of the two variable capacitors to produce an output signal at the first electrodes connected to each other of the two variable capacitors in the pair, the two AC voltages being relatively 90° out of phase with respect to each other, multiplying the output signal by two AC signals to produce two multiplication signals in the pair, the two AC signals being relatively 90° out of phase with respect to each other, and integrating the two multiplication signals for each cycle of the corresponding AC bias voltages to acquire two integration signals for the two variable capacitors in the pair.

Further features of the present invention will become apparent from the following description of exemplary embodiments with reference to the attached drawings.

### BRIEF DESCRIPTION OF THE DRAWINGS

FIG. 1 is an explanatory diagram of a drive circuit for a measuring device such as an ultrasonic transducer of the present invention.

FIGS. 2A, 2B, 2C and 2D are diagrams for describing signals in the measuring device of the present invention.

FIG. 3 is a diagram for describing a drive circuit and a drive method for the measuring device of the present invention.

FIGS. 4A and 4B are diagrams illustrating the top surface and the cross section of a configuration example of a capacitance type ultrasonic transducer, respectively.

FIG. 5 is a diagram illustrating an example of a subject diagnostic device using the measuring device of the present invention.

### DESCRIPTION OF THE EMBODIMENTS

The present invention is characterized by electrically connecting the first electrodes of the two variable capacitors to each other in each pair of a plurality of variable capacitors as sensor elements of a measuring device, applying two AC bias voltages which are relatively 90° out of phase with respect to each other to the second electrodes respectively of the two variable capacitors to produce an output signal at the first electrodes connected to each other in the pair, multiplying the output signal by two AC signals which are relatively 90° out of phase with respect to each other to produce two multiplication signals in the pair, and integrating the two multiplication signals for each cycle of the corresponding AC bias voltages to acquire two integration signals for the two variable capacitors in the pair. The present invention is not limited to a drive unit and method for a capacitance type ultrasonic transducer set forth in the embodiments described later, but is also applicable to a drive unit and a drive method for any measuring device as long as the measuring device has a plurality of variable capacitors as sensor elements.

Preferred embodiments of the present invention will now be described in detail in accordance with the accompanying drawings.

### First Embodiment

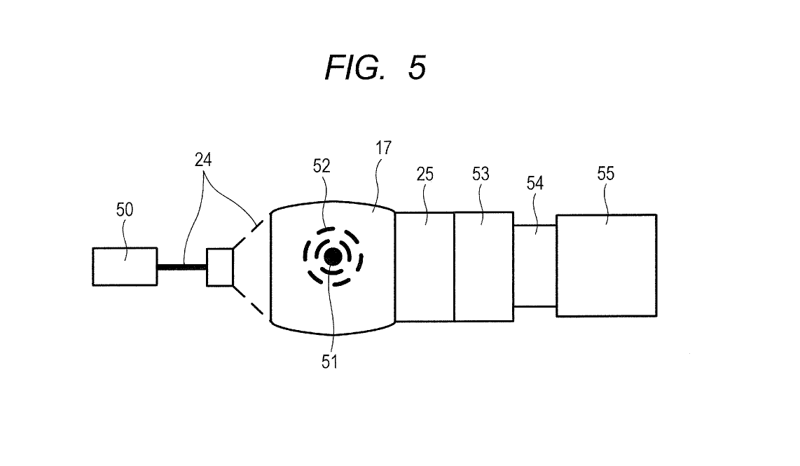

A first embodiment relates to a drive unit and method for a capacitance type ultrasonic transducer. First, description is made on an element constituting a variable capacitor of an ultrasonic transducer of this embodiment. As illustrated in FIGS. 4A and 4B, in one element 705, there are provided a first electrode 702 on a substrate 701 and a second electrode 703 on a membrane 707 with a cavity 704 therebetween. In this specification, a silicon wafer is used for the substrate 701. Although a Ti film is used for the first electrode 702 and the second electrode 703, any other electrode material may be used. In the case where the substrate 701 is made of low-resistivity silicon (for example, 0.01 ohm-cm or less), the arrangement may be made with the first electrode 702 omitted and the substrate 701 as a first electrode. A silicon dioxide film, which is an insulating film 706, is arranged between the first and second electrodes. The second electrode 703 is arranged on the membrane 707 such as a silicon nitride film and connected to an electrode pad 709 of the second electrode 703 via wiring 102. The first electrode 702 is connected to an electrode pad 708 of the first electrode 702. In this embodiment, four cells, each of which is the minimum unit of the ultrasonic transducer, constitute one element 705 with the second electrode 703 in which the four cells are connected to each other. A plurality of elements having this configuration is provided. As described later, two elements constitute one pair and a drive circuit is provided for each pair. Naturally, the configuration of the element 705 is not limited thereto, but may be configured appropriately.

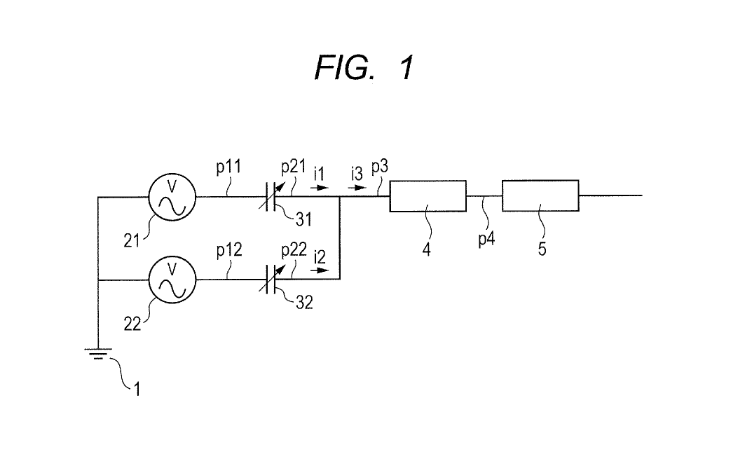

FIG. 1 is a diagram for describing the configuration of the drive unit of this embodiment. In FIG. 1, a reference numeral 1 denotes a ground potential and a drive unit for each pair composed of two elements includes a bias supply 21, a bias supply 22, an element 31 and an element 32 constituting one pair, a current-to-voltage converter 4, and a signal separator 5. For illustrative purposes, numbers p11, p12, p21, p22, p3, and p4 are appended to the wirings of FIG. 1 as illustrated. The ground potential 1 is a reference voltage of the circuit. The bias supply 21 applies a bias voltage to the wiring p11 with the ground potential 1 as a reference. Similarly, the bias supply 22 applies a bias voltage to the wiring p12. The element 31 and the element 32 are elements of an ultrasonic transducer having the configuration as described with reference to FIGS. 4A and 4B. As described in “Description of the Related Art”, the element 31 and the element 32 are equivalent to variable capacitors. A terminal of one electrode of the element 31 is connected to the bias supply 21 via the wiring p11 and a terminal of one electrode of the element 32 is connected to the bias supply 22 via the wiring p12. A terminal of the other electrode of the element 31 and that of the element 32 are connected to each other via the wiring p21 and the wiring p22 and then connected to the wiring p3. The wiring p3 is input to the current-to-voltage converter 4. The output of the current-to-voltage converter 4 is input to the signal separator 5 via the wiring p4. The wiring p3 is virtually grounded by an operational amplifier, which is not illustrated, in the current-to-voltage converter 4. Therefore, the wiring p3 can be considered to be equivalent to a ground potential.

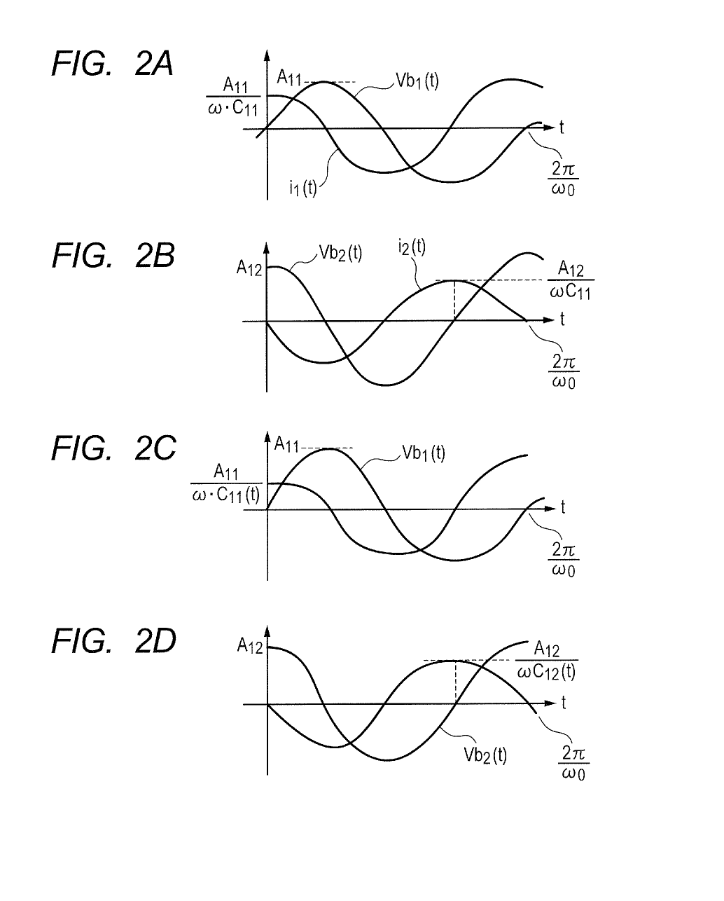

Subsequently, the operations of the bias supply 21, the bias supply 22, the element 31, and the element 32 will be described by using FIGS. 2A to 2D. In FIGS. 2A to 2D, the horizontal axis represents time t and the vertical axis represents voltage and current.

FIG. 2A is a diagram illustrating the operational relationship between the bias supply 21 and the element 31. FIG. 2A illustrates a case where the position of the membrane is fixed without any input of an ultrasonic vibration to the ultrasonic transducer. In this case, the capacitance of the element 31 is fixed. The current i₁(t) flowing through the wiring p21 depends on the voltage Vb₁(t) of the bias supply 21. The bias supply 21 generates a voltage Vb₁(t) in the following expression (1):

Vb₁(t)=A₁₁*sin(ω*t) (1)

In the above expression, t is time, ω is an angular velocity [rad/s], and A₁₁ is amplitude [V].

The angular velocity ω is set to a frequency higher than a frequency at which the membrane is able to vibrate mechanically, thereby preventing the vibration of the membrane from being caused by the bias supply 21. Specifically, the frequency of the AC bias voltage is set to a frequency higher than a mechanical vibration band of the element. In this condition, the current i₁(t) flowing through the wiring p21 is represented by the following expression (2):

i₁(t)=(A₁₁/(ω*C₁₁))*cos(ω*t) (2)

In the above expression, C₁₁ is the capacitance of the element 31.

FIG. 2B is a diagram illustrating the operational relationship between the bias supply 22 and the element 32. Similarly to FIG. 2A, FIG. 2B illustrates a case where the position of the membrane is fixed without any input of an ultrasonic vibration to the ultrasonic transducer. In this case, the capacitance of the element 32 is fixed. The current i₂(t) flowing through the wiring p22 depends on the voltage Vb₂(t) of the bias supply 22. The bias supply 22 generates a voltage Vb₂(t) in an expression (3) given below. This is an AC bias voltage which is relatively 90° out of phase with respect to the voltage Vb₁(t).

Vb₂(t)=A₁₂*cos(ω*t) (3)

In the above expression, t is time, ω is an angular velocity [rad/s], and A₁₂ is amplitude [V].

Also in this state, the angular velocity ω is set to a frequency higher than a frequency at which the membrane is able to vibrate mechanically, thereby preventing the vibration of the membrane from being caused by the bias supply 22. In this condition, the current i₂(t) flowing through the wiring p22 is represented by the following expression (4):

i₂(t)=−(A₁₂/(ω*C₁₂))*sin(ω*t) (4)

In the above expression, C₁₂ is the capacitance of the element 32.

FIG. 2C is a diagram for describing a case where ultrasonic vibration impinges on the element 31 and thereby the membrane mechanically causes vibration, by which the capacitance of the element 31 changes. The bias supply 21 generates a voltage Vb₁(t) in the following expression (1) which is equivalent to the expression (1) in FIG. 2A:

Vb₁(t)=A₁₁*sin(ω*t) (1)

The angular velocity ω is set to a frequency higher than a frequency at which the membrane is able to vibrate mechanically. In this condition, the current i₁(t) flowing through the wiring p21 is represented by the following expression (5):

i₁(t)=(A₁₁/(ω*C₁₁(t)))*cos(ω*t) (5)

In the above expression, C₁₁(t) is a time-varying capacitance of the element 31.

FIG. 2D is a diagram for describing a case where ultrasonic vibration impinges on the element 32 and thereby the membrane mechanically causes vibration, by which the capacitance of the element 32 changes. The bias supply 22 generates a voltage Vb₂(t) in the following expression (3) which is equivalent to the expression (3) in FIG. 2B:

Vb₂(t)=A₁₂*cos(ω*t) (3)

Also in this state, the angular velocity ω is set to a frequency higher than a frequency at which the membrane is able to vibrate mechanically. In this condition, the current i₂(t) flowing through the wiring p22 is represented by the following expression (6):

i₂(t)=−(A₁₂/(ω*C₁₂(t)))*sin(ω*t) (6)

In the above expression, C₁₂(t) is a time-varying capacitance of the element 32.

In the above expressions (5) and (6), the terms are defined as follows:

I₄₁(t)=(A₁₁/(ω*C₁₁(t)) (7)

I₄₂(t)=(A₁₂/(ω*C₁₂(t)) (8)

Then, the expressions (5) and (6) are evaluated as follows:

i₁(t)=I₄₁(t)*cos(ω*t) (9)

i₂(t)=−I₄₂(t)*sin(ω*t) (10)

The current i₃(t) flowing through the wiring p3 is represented based on Kirchhoff's laws by the following expression:

i₃(t)=i₁(t)+i₂(t) (11)

The current i₃(t) is defined using the expressions (9), (10), and (11) as follows:

i₃(t)=I₄₁(t)*cos(ω*t)−I₄₂(t)*sin(ω*t) (12)

The current-to-voltage converter 4, in which two currents flow, converts the current i₁(t) and the current i₂(t) to voltage V₃₁(t) and voltage V₃₂(t), respectively, as follows:

V₃₁(t)=E₃*I₄₁(t) (13)

V₃₂(t)−E₃*I₄₂(t) (14)

In the above expression, E₃ is a current-to-voltage conversion constant [V/I].

This type of circuit is feasible using a transimpedance circuit. The value of the current-to-voltage conversion constant E₃ is an arbitrary real number. The values of the transimpedance circuit and the current-to-voltage conversion constant E₃ are not the essence of the present invention and therefore the description of the values is omitted here. The voltage V₄(t) output from the current-to-voltage converter 4 is represented using the above expressions (12), (13), and (14) by the following expression (15):

V₄(t)=V₃₁(t)*cos(ω*t)−V₃₂(t)*sin(ω*t) (15)

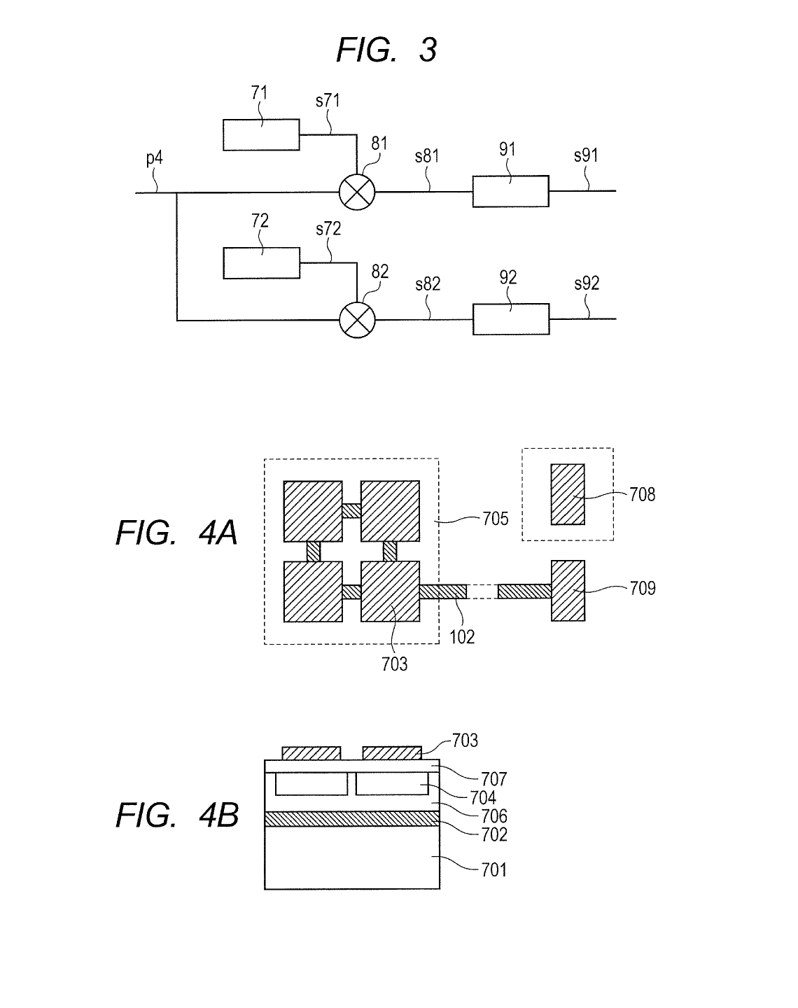

Subsequently, the operation of the signal separator 5 will be described by using FIG. 3. The function of the signal separator 5 is to separate and detect the voltage V₃₁(t) and the voltage V₃₂(t) from the voltage V₄(t) in the expression (15). As illustrated in FIG. 3, the signal separator 5 includes a reference signal generator 71, a reference signal generator 72, a multiplier 81, a multiplier 82, and an integrator 91, and an integrator 92. Reference numeral p4 denotes the wiring p4 in FIG. 1. For illustrative purposes, S71, S72, S81, S82, S91, and S92 are appended as signals in FIG. 3. Signals flowing through the wiring p4 are input to the multiplier and the multiplier 82. In addition, the reference signal S71 is input to the multiplier 81 and the reference signal S72 is input to the multiplier 82. The output of the multiplier 81 is input to the integrator 91 and the output of the multiplier 82 is input to the integrator 92.

A voltage signal represented by the expression (15) is input to the wiring p4 in FIG. 3.

V₄(t)=V₃₁(t)*cos(ω*t)−V₃₂(t)*sin(ω*t) (15)

The reference signal S71 output from the reference signal generator 71 is the following voltage signal of a cosine wave:

S71=V₅*cos(ω*t) (16)

In the above expression, t is time, V₅₁ is arbitrary amplitude [V], and ω is an angular velocity [rad/s]. The value of the angular velocity ω in the expression (16) is the same as the angular velocity ω in the expression (1).

The multiplier 81 multiplies the voltage V₄(t) by the reference signal S71 to generate the following signal S81:

S81=(V₃₁(t)*cos(ω*t)−V₃₂(t)*sin(ω*t))*(V₅₁*cos(ω*t)) (17)

The integrator 91 integrates the signal S81 and outputs the following signal S91:

S91=(1/(V₅₁*n))*F1 (18)

In the above expression, F1 represents a formula for integrating the signal S81 with respect to time t in the interval from time 0 to time (2 π/ω).

The value of the signal S91 in the expression (18) is an average value of the voltage V₃₁ from time 0 to time (2 π/ω).

On the other hand, the reference signal S72 output from the reference signal generator 72 is a voltage signal of a negative sine wave. This is an AC signal which is relatively 90° out of phase with respect to the reference signal S71.

S72=−V₅₂*sin(ω*t) (19)

In the above expression, V₅₂ is arbitrary amplitude [V].

The multiplier 82 multiplies the voltage V₄(t) by the reference signal S72 to generate the following signal S82:

S82=(V₃₁(t)*cos(ω*t)−V₃₂(t)*sin(ω*t))*(−V₅₂*sin(ω*t)) (20)

The integrator 92 integrates the signal S82 and outputs the following signal S92:

S92=(1/(V₅₂*π))*F2 (21)

In the above expression, F2 represents a formula for integrating the signal S82 with respect to time t in the interval from time 0 to time (2 π/ω).

The value of the signal S92 in the expression (21) is an average value of the voltage V₃₂ from time 0 to time (2 π/ω).

The voltage V₃₁ is represented by the expression (13) as follows:

V₃₁(t)=E₃*I₄₁(t) (13)

Then, when I₄₁(t)=(A₁₁/(ω*C₁₁(t)) in the expression (7) is substituted into the expression (13), the following expression is obtained:

V₃₁(t)=E₃*(A₁₁/(ω*C₁₁(t)) (22)

The current-to-voltage conversion constant E₃, the amplitude A₁₁ of the bias voltage, and the angular velocity ω of the bias voltage are known constants. When a constant F₁₁ is defined as in the following expression (23), the expression (22) is expressed by using the expression (23) as in the following expression (24):

F₁₁=(E₃*A₁₁)/ω (23)

V₃₁(t)=F₁₁/C₁₁(t) (24)

Similarly, when a constant F₁₂ is defined as in the following expression (25), an expression (26) is obtained:

F₁₂=(E₃*Aₗ₂)/ω (25)

V₃₂(t)=F₁₂/C₁₂(t) (26)

Since the capacitance C₁₁(t) and the capacitance C₁₂(t) are the capacitances of the element 31 and the element 32 of FIG. 1, respectively, the reference numerals V₃₁(t) and V₃₂(t) denote ultrasonic signals representing the displacements of the membranes of the element 31 and the element 32, respectively. In this manner, elements which are two variable capacitors of each pair are able to be driven by one drive circuit, and two ultrasonic signals, which correspond to the two elements, are able to be detected separately. Therefore, the number of drive circuits can be decreased without increasing the distance between the elements.

### Second Embodiment

Referring to FIG. 5, there is illustrated a subject diagnostic device or a photoacoustic measuring device which is a second embodiment of the present invention. A light source 50 is, for example, a light source generating a laser beam and light 24 is, for example, a pulsed laser beam.

In this device, irradiation light 24 projected from the light source 50 toward a subject 17 hits against a light absorber 51 inside the subject, thereby generating an acoustic wave 52, which is called “photoacoustic wave”, due to a photoacoustic effect. While the frequency of the acoustic wave 52 depends on the size of material and/or individual pieces constituting the light absorber 51, the frequency is on the order of 300 kHz to 10 MHz. The acoustic wave 52 passes through acoustic impedance matching material 25 with good propagation properties and is detected by a capacitance type ultrasonic transducer 53 having a drive unit of the present invention. A signal amplified in current and voltage is sent to a signal processing section 55 via a signal line 54. The detected signal is processed by the signal processing section 55 and physical information on the subject is extracted. Although the signal processing section 55 is mainly a calculator, a part of the signal processing section 55 may be an integrated circuit and it is possible to reconstruct the two- or three-dimensional image thereof. The use of the ultrasonic transducer 53 having the drive unit of the present invention enables the achievement of signals in a compact configuration. Naturally, the measuring device of the present invention is also able to be used in a subject diagnostic device which detects an acoustic wave from a subject to which an acoustic wave such as an ultrasonic wave is applied. Also in this case, the acoustic wave from the subject is detected and the converted signal is processed by a signal processing section, thereby enabling the acquisition of information on the inside of the subject.

According to the present invention, two variable capacitors, which are elements or the like of a capacitance type ultrasonic transducer, are able to be driven as one pair by one drive circuit and two signals (ultrasonic signals or the like) corresponding to the two variable capacitors of each pair, are able to be detected separately. Accordingly, the number of drive circuits, namely channels is able to be decreased without increasing the distance between variable capacitors such as elements.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-126095, filed Jun. 1, 2012, which is hereby incorporated by reference herein in its entirety.

What is claimed is:

1. A drive unit for a measuring device comprising a plurality of variable capacitors as sensor elements each having first and second electrodes opposed to each other, the plurality of variable capacitors being provided with a drive circuit for each pair,
wherein the first electrodes of the two variable capacitors in each pair are electrically connected to each other, and
wherein the drive circuit for each pair includes:
a bias supply which applies two AC bias voltages to the second electrodes respectively of the two variable capacitors in the pair to produce an output signal at the first electrodes connected to each other of the two variable capacitors in the pair, the two AC bias voltages being relatively 90° out of phase with respect to each other;
a multiplier which multiplies the output signal by two AC signals to produce two multiplication signals, the two AC signals being relatively 90° out of phase with respect to each other; and
an integrator which integrates the two multiplication signals for each cycle of the corresponding AC bias voltages to acquire two integration signals for the two variable capacitors.

2. The drive unit according to claim 1, wherein the plurality of variable capacitors are elements of a capacitance type ultrasonic transducer.

3. The drive unit according to claim 1, wherein the frequency of the two AC bias voltages is higher than the mechanical vibration band of the two variable capacitors.

4. A drive method for a measuring device comprising a plurality of variable capacitors as sensor elements each having first and second electrodes opposed to each other, the method comprising the steps of:
electrically connecting the first electrodes of the two variable capacitors in each pair of the plurality of variable capacitors;
applying two AC bias voltages to the second electrodes respectively of the two variable capacitors to produce an output signal at the first electrodes connected to each other of the two variable capacitors in the pair, the two AC bias voltages being relatively 90° out of phase with respect to each other;
multiplying the output signal by two AC signals to produce two multiplication signals in the pair, the two AC signals being relatively 90° out of phase with respect to each other; and
integrating the two multiplication signals for each cycle of the corresponding AC bias voltages to acquire two integration signals for the two variable capacitors in the pair.

5. The drive method according to claim 4, wherein the frequency of the two AC bias voltages is higher than the mechanical vibration band of the two variable capacitors.
